(19) United States
(12) Patent Application Publication
(10) Pub. No.: US 2025/0228052 A1
(43) Pub. Date: Jul. 10, 2025

(54) LIGHT-EMITTING BASEPLATE AND PREPARATION METHOD THEREOF, AND LIGHT-EMITTING DEVICE

(71) Applicant: BOE Technology Group Co., Ltd., Beijing (CN)

(72) Inventors: Jiaxiang Zhang, Beijing (CN); Yan Qu, Beijing (CN); Xinxin Zhao, Beijing (CN); Nianqi Yao, Beijing (CN)

(73) Assignee: BOE Technology Group Co., Ltd., Beijing (CN)

(21) Appl. No.: 18/701,818

(22) PCT Filed: Mar. 15, 2023
(86) PCT No.: PCT/CN2023/081752

§ 371 Date: Apr. 16, 2024

(51) Int. Cl. H10H 29/49; H10H 29/01

(52) U.S. Cl. CPC H10H 29/49; H10H 29/012

(57) ABSTRACT

A light-emitting baseplate and a preparation method thereof, and a light-emitting device, relate to the technical field of displays. The light-emitting baseplate includes: a substrate; and a first metal pattern disposed on a side of the substrate, including a first surface away from the substrate, a second surface close to the substrate, and a first side surface connecting the first surface and the second surface, the first surface including a middle region, and an edge region at a periphery of the middle region; wherein the first surface protrudes toward a side away from the substrate, and a protrusion height of the middle region is greater than a protrusion height of the edge region.

### TECHNICAL FIELD

The present disclosure relates to the technical field of displays and more particularly, to a light-emitting baseplate and a preparation method thereof, and a light-emitting device.

### BACKGROUND

Compared with liquid crystal display screens and organic light-emitting diode display screen, light-emitting diode (LED) display screen has obvious advantages in image quality, refresh frequency, power consumption and brightness. These advantages make LED displays have a wide range of applications, such as traditional displays, near-eye displays, 3D displays, and transparent displays.

### SUMMARY

The present disclosure provides a light-emitting baseplate including:
a substrate; and
a first metal pattern disposed on a side of the substrate, and including a first surface away from the substrate, a second surface close to the substrate, and a first side surface connecting the first surface and the second surface, wherein the first surface includes a middle region, and an edge region at a periphery of the middle region;
wherein the first surface protrudes toward a side away from the substrate, and a protrusion height of the middle region is greater than a protrusion height of the edge region.

In some embodiments, the first surface further comprises:
a sub-middle region, located between the middle region and the edge region, wherein a protrusion height of the sub-middle region is less than the protrusion height of the middle region and greater than the protrusion height of the edge region.

In some embodiments, a protrusion height of the first surface gradually decreases from a center of the first surface to an edge of the first surface; and
a ratio of a difference between the protrusion heights of the middle region and the edge region to the protrusion height of the edge region is greater than or equal to 0.1, and less than or equal to 0.4.

In some embodiments, an orthographic projection of the first surface on the substrate covers an orthographic projection of the second surface on the substrate, and an area of the orthographic projection of the first surface on the substrate is larger than an area of the orthographic projection of the second surface on the substrate.

In some embodiments, an included angle between the first side surface and the second surface is greater than or equal to 80°, and less than or equal to 120°.

In some embodiments, the first metal pattern further comprises:
a first cross section, parallel to the substrate and intersecting an edge of the first surface, wherein an included angle between the first cross section and the first side surface is an acute angle.

In some embodiments, the first side surface is provided with a groove recessed toward inside of the first metal pattern, the groove is located at a position of the first side surface close to the substrate.

In some embodiments, the light-emitting baseplate further comprises:
a second metal pattern, disposed on a side of the first metal pattern away from the substrate, wherein the second metal pattern completely covers the first surface and the first side surface.

In some embodiments, the second metal pattern is provided with a fine seam close to a position where the first side surface intersects the second surface.

In some embodiments, the light-emitting baseplate further comprises:
a passivation layer, disposed on a side of the first metal pattern away from the substrate, wherein a first opening is provided on the passivation layer, the first opening is used for exposing the middle region of the first surface, and the passivation layer covers at least the edge region of the first surface and the first side surface; and
a second metal pattern, disposed on a side of the passivation layer away from the substrate, wherein the second metal pattern completely covers the middle region of the first surface, an orthographic projection of the second metal pattern on the substrate at least partially covers an orthographic projection of the passivation layer on the substrate.

In some embodiments, a boundary of the orthographic projection of the second metal pattern on the substrate is located between a boundary of an orthographic projection of the first opening on the substrate and a boundary of an orthographic projection of the first metal pattern on the substrate.

In some embodiments, a boundary of the orthographic projection of the second metal pattern on the substrate is located on a side of a boundary of an orthographic projection of the first metal pattern on the substrate away from the orthographic projection of the first opening on the substrate.

In some embodiments, the light-emitting baseplate further comprises:
a flat layer, located between the passivation layer and the second metal pattern, wherein an orthographic projection of the flat layer on the substrate completely overlaps the orthographic projection of the passivation layer on the substrate, a surface of a side of the flat layer away from the substrate is a plane parallel to the substrate.

In some embodiments, the light-emitting baseplate further comprises:
an isolation layer, disposed between the flat layer and the second metal pattern, wherein a second opening is provided on the isolation layer, an orthographic projection of the second opening on the substrate at least partially overlaps an orthographic projection of the first opening on the substrate, the isolation layer covers a surface of the flat layer facing the second metal pattern and a side surface of the flat layer facing the first opening.

In some embodiments, the flat layer comprises a first flat pattern overlapping the first metal pattern in a normal direction of the substrate, a thickness of the first flat pattern is greater than 0, and less than or equal to 1 μm.

In some embodiments, a thickness of the second metal pattern on a side of the first metal pattern away from the substrate is greater than or equal to 2,000 angstroms, and less than or equal to 6,000 angstroms.

In some embodiments, a thickness of the passivation layer on a side of the first metal pattern away from the substrate is greater than or equal to 2,000 angstroms.

In some embodiments, a boundary of an orthographic projection of the first metal pattern on the substrate is located within a boundary of an orthographic projection of the second metal pattern on the substrate, and a distance between the boundary of the orthographic projection of the first metal pattern on the substrate and the boundary of the orthographic projection of the second metal pattern on the substrate is greater than or equal to 0.5 μm, and less than or equal to 1.5 μm.

In some embodiments, the boundary of the orthographic projection of the first opening on the substrate is located within the boundary of the orthographic projection of the second metal pattern on the substrate, and a distance between the boundary of the orthographic projection of the first opening on the substrate and the boundary of the orthographic projection of the second metal pattern on the substrate is greater than or equal to 1 μm, and less than or equal to 3 μm.

In some embodiments, a material of the second metal pattern comprises at least one of nickel vanadium alloys, nickel tungsten alloys, and copper-nickel alloys.

In some embodiments, an included angle formed by the intersection of the first surface and the first side surface is a rounded angle.

In some embodiments, a thickness of the first metal pattern is greater than or equal to 4 μm, and less than or equal to 10 μm.

The present disclosure provides a light-emitting device, comprising:
the light-emitting baseplate according to any one of the above embodiments; and
a light-emitting diode, disposed on a side of the first metal pattern away from the substrate, and connected to the first metal pattern, wherein the first metal pattern is used for providing a driving signal to the light-emitting diode, to drive the light-emitting diode to emit light.

The present disclosure provides a preparation method of a light-emitting baseplate, comprising:
providing a substrate;
forming a first metal pattern on a side of the substrate, wherein the first metal pattern comprises: a first surface away from the substrate, a second surface close to the substrate, and a first side surface connecting the first surface and the second surface, the first surface comprises a middle region, and an edge region at a periphery of the middle region; wherein the first surface protrudes toward a side away from the substrate, and a protrusion height of the middle region is greater than a protrusion height of the edge region.

In some embodiments, the step of forming a first metal pattern on a side of the substrate comprises:
forming a seed layer on a side of the substrate;
patterning to form a pattern defining layer on a side of the seed layer away from the substrate, wherein a material of the pattern defining layer is a removable insulating material, the pattern defining layer is provided with a plurality of openings to expose the seed layer at corresponding positions;
forming a first metal material layer within openings of the pattern defining layer;
removing the pattern defining layer;
removing a portion of the seed layer not covered by the first metal material layer using an etching process to form the first metal pattern, wherein the first metal pattern comprises a seed layer and a first metal material layer remaining after the etching process is completed.

In some embodiments, an included angle between a side surface of the pattern defining layer facing the opening and a bottom surface of the pattern defining layer close to the substrate is greater than or equal to 60°, and less than or equal to 100°.

In some embodiments, the pattern defining layer comprises at least one of:
a resin material, having a relative molecular weight greater than or equal to 30000 and less than or equal to 50000; and
a sensitizer, having a mass fraction greater than or equal to 20%.

The above description is only an overview of the technical solution of the present disclosure. In order to have a clearer understanding of the technical means of the present disclosure, it can be implemented according to the content of the specification. In order to make the above and other purposes, features, and advantages of the present disclosure more obvious and easier to understand, the specific implementation methods of the present disclosure are listed below.

### BRIEF DESCRIPTION OF THE DRAWINGS

In order to provide a clearer explanation of the technical solutions in the embodiments of the present disclosure or related art, a brief introduction will be given below to the accompanying drawings required in descriptions of the embodiments or related technical. It is obvious that the accompanying drawings in the following description are some embodiments of the present disclosure. For those skilled in the art, other accompanying drawings can be obtained based on these drawings without creative labor. It should be noted that the proportions in the accompanying drawings are only for illustrative purposes and do not represent the actual proportions.

FIG. 1 schematically shows a schematic diagram of the cross-sectional structure of a light-emitting baseplate provided by the present disclosure;

FIG. 2 to FIG. 8 schematically show a schematic diagram of the cross-sectional structure of several embodiments of a light-emitting baseplate;

FIG. 9 shows optical reflectivity-wavelength curves for nickel vanadium alloys under several annealing conditions;

FIG. 10 shows a topographical diagram of solder paste after reflow;

FIG. 11 shows a cross-sectional view of a light-emitting baseplate;

FIG. 12 shows a cross-sectional view of another light-emitting baseplate; and

FIG. 13 shows a cross-sectional view of a pattern defining layer.

### DETAILED DESCRIPTION

In order to clarify the purpose, technical solution, and advantages of the embodiments of the present disclosure, the following will provide a clear and complete description of the technical solution in the embodiments of the present disclosure in conjunction with the accompanying drawings. Obviously, the described embodiments are a part of the embodiments of the present disclosure, not all of them. Based on the embodiments of the present disclosure, all other embodiments obtained by persons skilled in the art without creative labor fall within the scope of protection of the present disclosure.

In the related art, a light-emitting baseplate includes a driving substrate and a light-emitting element soldered on the driving substrate, among them, the light-emitting element and the driving substrate are soldered by using solder. The inventors have found that the conventional light-emitting baseplate has a problem in that a soldering void ratio is large, resulting in large contact resistance between the light-emitting element and the driving substrate and a decrease in photoelectric conversion efficiency.

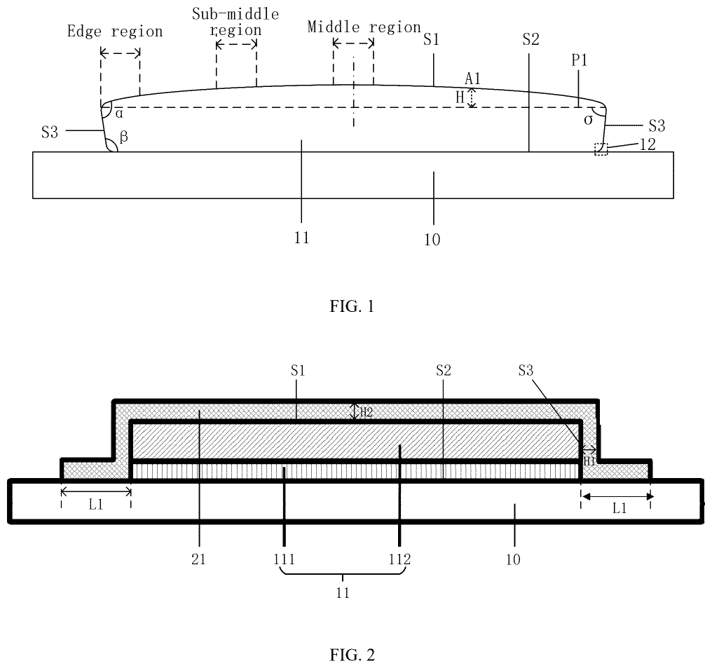

Referring to FIG. 1, FIG. 1 schematically shows a schematic diagram of the cross-sectional structure of a light-emitting baseplate provided by the present disclosure, and as shown in FIG. 1, the light-emitting baseplate includes a substrate 10 and a first metal pattern 11 disposed on a side of the substrate 10, the first metal pattern 11 includes: a first surface S1 away from the substrate 10, a second surface S2 close to the substrate 10, and a first side surface S3 connecting the first surface S1 and the second surface S2; the first surface S1 includes a middle region, and an edge region located at the periphery of the middle region. Among them, the first surface S1 protrudes toward a side away from the substrate 10, and the protrusion height of the middle region is larger than that of the edge region.

As shown in FIG. 1, the first metal pattern 11 further includes a first cross section P1 parallel to the substrate 10 and intersecting an edge of the first surface S1.

In the present disclosure, as shown in FIG. 1, for any point A1 on the first surface S1, the protrusion height H of the point A1 is the distance between the point A1 and the first cross section P1.

Illustratively, as shown in FIG. 1, the middle region is a region of the first surfaces S1 close to the center of the first surface S1. The edge region is the region of the first surface S1 close to the edge of the first surface S1.

When a light-emitting element such as an LED is soldered on the side of the first surface S1 away from the substrate 10, since the protrusion height in the middle region of the first surface S1 is greater than the protrusion height of the edge region, the light-emitting element first contacts the middle region of the first surface S1 during the soldering process, so that air bubbles in the solder can be timely discharged before the light-emitting element contacts the edge region, thereby reducing the soldering void ratio, improving the soldering robustness, reducing the contact resistance, and thus improving the photoelectric conversion rate and reliability.

In some embodiments, as shown in FIG. 1, the first surface S1 further includes a sub-middle region located between the middle region and the edge region, and the protrusion height of the sub-middle region is less than the protrusion height of the middle region and greater than the protrusion height of the edge region.

As shown in FIG. 1, since the protrusion heights of the middle region, the sub-middle region, and the edge region are successively reduced, during the soldering process, the light-emitting element first contacts the middle region of the first surface S1, and bubbles in the solder in the middle region can be discharged in time before the light-emitting element contacts the sub-middle region, and then the light-emitting element contacts the sub-middle region, and bubbles in the solder in the sub-middle region can be discharged in time before the light-emitting element contacts the edge region. This embodiment can further reduce the soldering void ratio, improve the soldering firmness, and reduce the contact resistance. Furthermore, the photoelectric conversion rate and reliability are improved.

In some embodiments, as shown in FIG. 1, the protrusion height on the first surface S1 gradually decreases from the center of the first surface S1 to the edge of the first surface S1. This can further reduce the soldering void ratio.

As shown in FIG. 1, the top surface of the first metal pattern 11 forms a mushroom-shaped bulge, the height of which is larger at the center of the first surface S1, and gradually decreases as approaches to the edge of the first surface S1. When the second surface S2 is a plane, as shown in FIG. 1, the thickness of the first metal pattern 11 gradually decreases from the center of the first surface S1 to the edge of the first surface S1.

In some embodiments, the difference between the protrusion height of the middle region and the protrusion height of the edge region can be greater than or equal to 1 μm, and less than or equal to 2 μm, such as 1.5 μm, etc.

In some embodiments, the ratio of the difference between the protrusion heights of the middle region and the edge region to the protrusion height of the edge region is greater than or equal to 0.1, and less than or equal to 0.4, such as 0.2, 0.3, etc.

In some embodiments, the material of the first metal pattern 11 may include, for example, one or more of copper, silver, gold, and the like.

In some embodiments, the included angle α formed by the intersection of the first surface S1 and the first side surface S3 is a rounded angle. As shown in FIG. 1, the included angle α is a rounded angle, rather than a sharp corner, which facilitates a complete covering of the first metal pattern 11, in particular the first side surface S3, by the subsequent film layer, resulting in a better protection of the first metal pattern 11.

In some embodiments, the included angle σ between the first cross section P1 and the first side surface S3 is an acute angle.

For the subsequent film layer to completely cover the first side surface S3 of the first metal pattern 11, in some embodiments, the included angle σ between the first cross section P1 and the first side surface S3 may be an acute angle greater than or equal to 60°, such as 70°, 80° etc.

In some embodiments, as shown in FIG. 1, the orthographic projection of the first surface S1 on the substrate 10 covers the orthographic projection of the second surface S2 on the substrate 10, and the area of the orthographic projection of the first surface S1 on the substrate is greater than the area of the orthographic projection of the second surface S2 on the substrate 10.

As shown in FIG. 1, the longitudinal cross-section (perpendicular to the substrate 10) of the first metal pattern 11 is shaped like an inverted trapezoid, the short side of the inverted trapezoid is close to the substrate 10 and the long side of inverted trapezoid is a convex arc.

The inventors have found that the thickness of the first metal pattern 11 is reduced every time the light emitting element is replaced or repaired, resulting in a limited number of repairable times or an increased resistance of the first metal pattern 11. To solve this problem, in some embodiments, the thickness of the first metal pattern 11 is greater than or equal to 4 μm and less than or equal to 10 μm, such as 5 μm, 6 μm, 8 μm, 9 μm, etc.

In this way, by providing the first metal pattern 11 with a larger thickness, the resistance of the first metal pattern 11 can be reduced to satisfy the requirement of high partition and high brightness, and the number of repairable times of the light-emitting elements can be increased to improve the performance and reliability of the light-emitting baseplate.

In some embodiments, as shown in FIG. 1, the included angle β between the first side surface S3 and the second surface S2 is less than or equal to 120°. This facilitates a complete covering of the first metal pattern 11, in particular the first side surface S3, by the subsequent film layer, resulting in better anti-oxidation protection.

Further, as shown in FIG. 1, the included angle β between the first side surface S3 and the second surface S2 may be greater than or equal to 80°, for example, the included angle β between the first side surface S3 and the second surface S2 may be 90°, 100°, 110° etc.

In some embodiments, as shown in FIG. 1, the first side surface S3 is provided with a groove 12 recessed towards the inside of the first metal pattern 11, the groove 12 is located at a position of the first side surface S3 close to the substrate 10. The groove 12 may be located at a position where the first side surface S3 intersects the second surface S2, and may also be located at a position on the first side surface S3 closer to the position where the first side surface S3 intersects the second surface S2.

After verification, in the case where the included angle β between the first side surface S3 and the second surface S2 is less than or equal to 120°, the groove 12 on the first side surface S3 can be substantially wrapped by the subsequent film layers, and there is no obvious oxidation of the first metal pattern 11, without affecting the product reliability.

In order to prevent oxidation of the material of the first metal pattern 11, in some embodiments, as shown in FIG. 2, the light-emitting baseplate further includes: a second metal pattern 21 disposed on the side of the first metal pattern 11 away from the substrate 10, and the second metal pattern 21 completely covers the first surface S1 and the first side surface S3.

As shown in FIG. 2, the second metal pattern 21 completely wraps the exposed first surface S1 and first side surface S3 of the first metal pattern 11, thereby protecting the material of the first metal material from oxidation in all directions.

To ensure that the second metal pattern 21 fully covers the first side surface S3, in some embodiments, as shown in FIG. 2, the thickness H1 of the second metal pattern 21 on the first side surface S3 is greater than or equal to 500 angstroms. This results in a good oxidation resistance of the first side surface S3.

In practice, the thickness H1 of the second metal pattern 21 on the first side surface S3 is less than the thickness H2 of the second metal pattern 21 on the first surface S1 due to the film forming process, the thickness of the first metal pattern 11 and the angle of the first side surface S3. Illustratively, the thickness H1 of the second metal pattern 21 on the first side surface S3 is ¼ of the thickness H2 of the second metal pattern 21 on the first surface S1, and thus, to ensure that the thickness H1 of the second metal pattern 21 on the first side surface S3 is greater than or equal to 500 angstroms, the thickness H2 of the second metal pattern 21 on the first surface S1 may be greater than or equal to 2000 angstroms.

In some embodiments, the thickness H2 of the second metal pattern 21 on the first surface S1 may be less than or equal to 6000 angstroms, which will not be limited by the present disclosure.

Illustratively, a magnetron sputtering process may be used to form a film, and then the second metal pattern 21 may be patterned using a photolithographic process.

As shown in FIG. 2, the orthographic projection of the second metal pattern 21 on the substrate 10 completely covers the orthographic projection of the first metal pattern 11 on the substrate 10, and the area of the orthographic projection of the second metal pattern 21 on the substrate 10 is larger than the area of the orthographic projection of the first metal pattern 11 on the substrate 10.

To ensure that the second metal pattern 21 completely covers the first metal pattern 11, in some embodiments, as shown in FIG. 2, a boundary of the orthographic projection of the first metal pattern 11 on the substrate 10 is within a boundary of the orthographic projection of the second metal pattern 21 on the substrate 10, and the distance (L1 as shown in FIG. 2) between the boundary of the orthographic projection of the first metal pattern 11 on the substrate 10 and the boundary of the orthographic projection of the second metal pattern 21 on the substrate 10 is greater than or equal to 0.5 μm, and less than or equal to 1.5 μm.

As shown in FIG. 2, the distance between the boundary of the orthographic projection of the first metal pattern 11 on the substrate 10 and the boundary of the orthographic projection of the second metal pattern 21 on the substrate 10 is defined as a first package length L1. The design value for the first package length L1 can be set to 1 μm, and the finally formed first package length L1 is typically greater than or equal to 0.5 μm and less than or equal to 1.5 μm due to the presence of alignment errors between the various layers in the manufacturing process. In this way, it is possible to prevent the position of the second metal pattern 21 from being seriously shifted due to the alignment deviations, thereby causing the first metal pattern 11 to be exposed, and this embodiment ensures that the first metal pattern 11 is completely covered by the second metal pattern 21.

In the specific implementation, the second metal pattern 21 formed by the magnetron sputtering film-forming process tends to have a fine seam structure (as shown in the circle position in FIG. 11) at the position where the first side surface S3 intersects the second surface S2. Thus, in some embodiments, the second metal pattern 21 may have a fine seam close to where the first side surface S3 intersects the second surface S2.

The inventors performed a compositional analysis of the first metal pattern 11 at the fine seam structure, and as a result, no significant oxidation was observed, and the influence on the reliability of the product is negligible.

In order to prevent oxidation of the material of the first metal pattern 11, in some embodiments, as shown in any one of FIG. 3 to FIG. 8, the light-emitting baseplate further includes: a passivation layer 31 disposed on a side of the first metal pattern 11 away from the substrate 10, wherein the passivation layer 31 is provided with a first opening V1, the first opening V1 is used for exposing the middle region of the first surface S1, and the passivation layer 31 covers at least the edge region of the first surface S1 and the first side surface S3; and a second metal pattern 21 disposed on a side of the passivation layer 31 away from the substrate 10, wherein the second metal pattern 21 completely covers a middle region of the first surface S1, and an orthographic projection of the second metal pattern 21 on the substrate 10 at least partially covers the orthographic projection of the passivation layer 31 on the substrate 10.

As shown in any one of FIG. 3 to FIG. 8, the first surface S1 may be divided into a middle region, and an edge region located at the periphery of the middle region. The passivation layer 31 comprehensively wraps the edge region of the first surface S1 and the first side surface S3. Illustratively, a passivation material layer may first be integrally formed on the side whole-surface of the first metal pattern 11 away from the substrate 10, that is, the orthographic projection of the passivation material layer on the substrate 10 covers the substrate 10 with the whole surface. The passivation material layer is then perforated, that is, the passivation material layer covering the middle region of the first surface S1 is removed, the first opening V1 is formed, resulting in the passivation layer 31.

By forming the first opening V1 in the passivation layer 31, soldering of the light-emitting element on the first metal pattern 11 or through-hole connection of the subsequent conductive layer with the first metal pattern 11 is facilitated.

In a particular implementation, the light-emitting baseplate may include a plurality of first metal patterns 11, wherein a part of the first metal patterns 11 may be used for soldering light-emitting diodes, and a part of the first metal patterns 11 may be connected to the conductive layer by through-hole connection.

To ensure that the passivation layer 31 fully covers the first side surface S3, in some embodiments, as shown in any one of FIG. 3 to FIG. 8, the thickness H3 of the passivation layer 31 on the first side surface S3 is greater than or equal to 1000 angstroms. This results in better anti-oxidation protection for the first side surface S3.

In specific implementation, as shown in any one of FIG. 3 to FIG. 8, the thickness H3 of the passivation layer 31 on the first side surface S3 is less than the thickness H4 of the passivation layer 31 on the first surface S1 due to factors such as the film forming process, the thickness of the first metal pattern 11, and the angle of the first side surface S3. Illustratively, the thickness H3 of the passivation layer 31 on the first side surface S3 is generally ½ of the thickness H4 of the passivation layer 31 on the first surface S1. To ensure that the thickness H3 of the passivation layer 31 on the first side surface S3 is greater than or equal to 1000 angstroms, the thickness H4 of the passivation layer 31 on the first surface S1 may be greater than or equal to 2000 Angstroms.

Illustratively, a chemical vapor deposition process may be used to form a film, and then the passivation layer 31 may be patterned by using a photolithographic process.

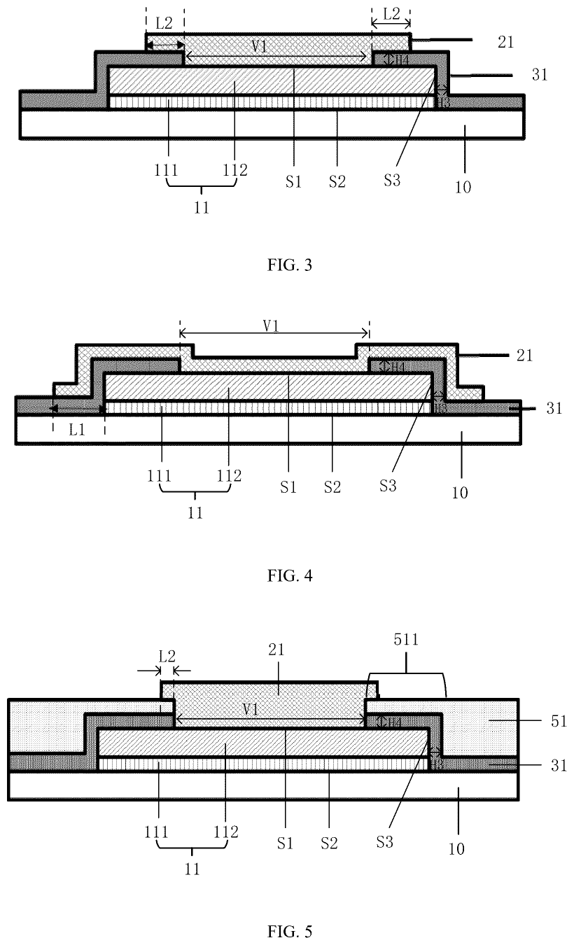

In specific implementation, the second metal pattern 21 may have various embodiments. For example, in the first embodiment, as shown in FIG. 3, FIG. 5, or FIG. 7, the boundary of the orthographic projection of the second metal pattern 21 on the substrate 10 is located between the boundary of the orthographic projection of the first opening V1 on the substrate 10 and the boundary of the orthographic projection of the first metal pattern 11 on the substrate 10.

Illustratively, as shown in FIG. 3, FIG. 5, or FIG. 7, the edge region of the first surface S1 covered by the passivation layer 31 may be further divided into a first edge region and a second edge region, the first edge region is close to the middle region. Among them, the orthographic projection of the second metal pattern 21 on the substrate 10 completely covers the middle region and the orthographic projection of the first edge region on the substrate 10, without overlapping with the orthographic projection of the second edge region on the substrate 10.

As shown in FIG. 3, FIG. 5, or FIG. 7, the orthographic projection of the second metal pattern 21 on the substrate 10 completely covers the orthographic projection of the first opening V1 on the substrate 10, and the area of the orthographic projection of the second metal pattern 21 on the substrate 10 is larger than the area of the orthographic projection of the first opening V1 on the substrate 10.

To ensure that the second metal pattern 21 completely covers the middle region, illustratively, as shown in FIG. 3, FIG. 5, or FIG. 7, the boundary of the orthographic projection of the first opening V1 on the substrate 10 is located within the boundary of the orthographic projection of the second metal pattern 21 on the substrate 10, and the distance (L2 as shown in figures) between the boundary of the orthographic projection of the first opening V1 on the substrate 10 and the boundary of the orthographic projection of the second metal pattern 21 on the substrate 10 is greater than or equal to 1 μm, and less than or equal to 3 μm.

For convenience of description, as shown in FIG. 3, FIG. 5, or FIG. 7, the distance between the boundary of the orthographic projection of the first opening V1 on the substrate 10 and the boundary of the orthographic projection of the second metal pattern 21 on the substrate 10 is defined as the second package length L2. The design value for the second package length can be set to 2 μm, and the finally formed second package length L2 is typically greater than or equal to 1 μm and less than or equal to 3 μm due to alignment errors between different layers in the manufacturing process.

In this way, it is possible to prevent the position of the second metal pattern 21 from being shifted due to the alignment deviation, thereby causing the first metal pattern 11 to be exposed, and this embodiment can ensure that the middle region not covered by the passivation layer 31 is completely covered by the second metal pattern 21.

By providing the passivation layer 31 between the first metal pattern 11 and the second metal pattern 21, the passivation layer 31 can fill and stack the recess where the first side surface S3 shrinks inward and the groove 12 on the first side surface S3, etc., thereby facilitating the second metal pattern 21 to comprehensively cover the first side surface S3, improving the fine seam problem at the intersection position of the first side surface S3 and the second surface S2, and enhancing the anti-oxidation protection of the first metal pattern 11.

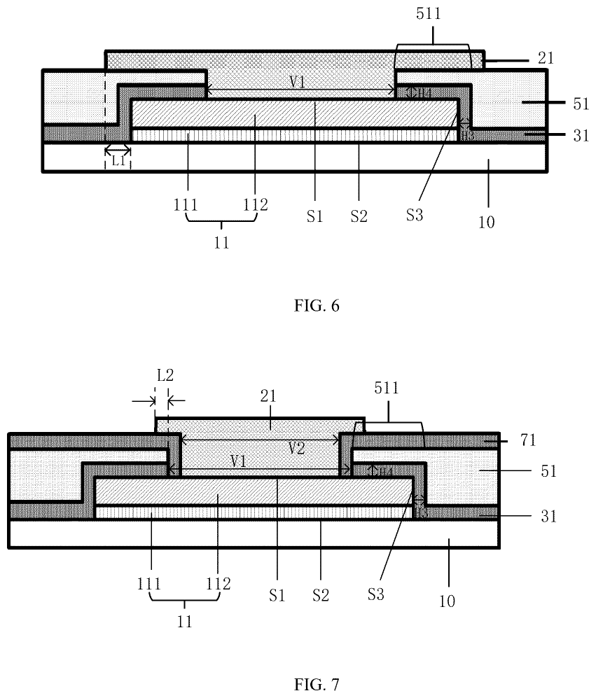

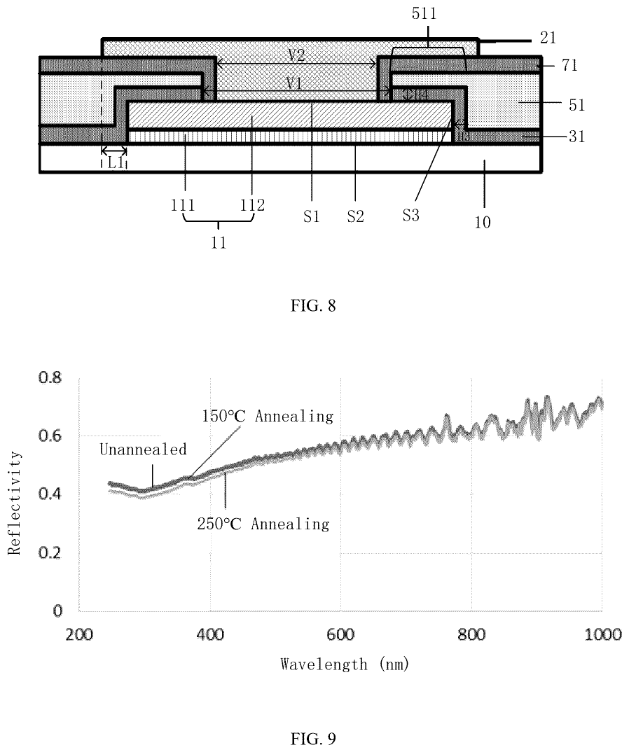

In the second embodiment, as shown in FIG. 4, FIG. 6, or FIG. 8, the boundary of the orthographic projection of the second metal pattern 21 on the substrate 10 is located on the side of the boundary of the orthographic projection of the first metal pattern 11 on the substrate 10 away from the orthographic projection of the first opening V1 on the substrate 10.

As shown in FIG. 4, FIG. 6, or FIG. 8, the orthographic projection of the second metal pattern 21 on the substrate 10 completely covers the orthographic projection of the first metal pattern 11 on the substrate 10, and the area of the orthographic projection of the second metal pattern 21 on the substrate 10 is larger than the area of the orthographic projection of the first metal pattern 11 on the substrate 10.

Illustratively, as shown in FIG. 4, FIG. 6, or FIG. 8, the boundary of the orthographic projection of the first metal pattern 11 on the substrate 10 is located within the boundary of the orthographic projection of the second metal pattern 21 on the substrate 10, and the distance (L1 as shown in figures) between the boundary of the orthographic projection of the first metal pattern 11 on the substrate 10 and the boundary of the orthographic projection of the second metal pattern 21 on the substrate 10 is greater than or equal to 0.5 μm and less, than or equal to 1.5 μm.

As shown in FIG. 4, FIG. 6, or FIG. 8, the distance between the boundary of the orthographic projection of the first metal pattern 11 on the substrate 10 and the boundary of the orthographic projection of the second metal pattern 21 on the substrate 10 is defined as the first package length L1. The design value for the first package length L1 can be set to 1 micron, and the finally formed first package length L1 is typically greater than or equal to 0.5 μm and less than or equal to 1.5 μm due to the presence of alignment errors between the various layers in the manufacturing process.

In the first embodiment, as shown in FIG. 3, FIG. 5, or FIG. 7, since the orthographic projection of the second metal pattern 21 on the substrate 10 does not completely cover the orthographic projection of the first surface S1 on the substrate 10, the area of the second metal pattern 21 is relatively small, and thus the stress of the light-emitting baseplate is less, which can improve the warping problem of the light-emitting baseplate that may be caused by excessive stress.

In the second embodiment, as shown in FIG. 4, FIG. 6, or FIG. 8, since the orthographic projection of the second metal pattern 21 on the substrate 10 completely covers the orthographic projection of the first surface S1 on the substrate 10, it is possible to form a dual protection composed by the passivation layer 31 and the second metal pattern 21, thereby enhancing the anti-oxidation protection of the first metal pattern 11.

In some embodiments, as shown in any one of FIG. 5 to FIG. 8, the light-emitting baseplate further includes a flat layer 51, located between the passivation layer 31 and the second metal pattern 21, wherein the orthographic projection of the flat layer 51 on the substrate 10 completely overlaps the orthographic projection of the passivation layer 31 on the substrate 10, and the surface of the side of the flat layer 51 away from the substrate 10 is a plane parallel to the substrate 10, so that the flatness of the light-emitting baseplate can be improved.

In order to improve the flatness of the surface of the side of the flat layer 51 away from the substrate 10, the thickness of the flat layer 51 may be greater than or equal to 90% of the thickness of the first metal pattern 11, and less than or equal to 110% of the thickness of the first metal pattern 11.

In some embodiments, as shown in any one of FIG. 5 to FIG. 8, the flat layer 51 includes a first flat pattern 511 overlapping the first metal pattern 11 in a normal direction of the substrate 10, the thickness of the first flat pattern 511 is greater than 0 and less than or equal to 1 μm. In this way, it is possible to avoid the formation of a deep hole at the first opening V1 while improving the flatness of the surface of the light-emitting baseplate.

Illustratively, the flat layer 51 may include, for example, one or more resin materials such as acryl resin and polyimide resin, and the present disclosure is not limited thereto.

In some embodiments, as shown in FIG. 7 or FIG. 8, the light-emitting baseplate further includes: an isolation layer 71, which is disposed between the flat layer 51 and the second metal pattern 21, wherein the isolation layer 71 is provided with a second opening V2, the orthographic projection of the second opening V2 on the substrate 10 at least partially overlaps the orthographic projection of the first opening V1 on the substrate 10, and the isolation layer 71 covers the surface of the flat layer 51 facing the second metal pattern 21 and the side surface of the flat layer 51 facing the first opening V1.

As shown in FIG. 7 or FIG. 8, the orthographic projection of the first opening V1 on the substrate 10 covers the orthographic projection of the second opening V2 on the substrate 10, and the area of the orthographic projection of the first opening V1 on the substrate 10 is larger than the area of the orthographic projection of the second opening V2 on the substrate 10.

By providing the isolation layer 71 to cover the surface of the flat layer 51, the adhesion of the second metal pattern 21 can be improved, and the flat layer 51 can be isolated from the outside, the outside water and oxygen intrusion can be prevented, and the material of the flat layer 51 can be prevented from absorbing water or from oxidizing.

In some embodiments, the material of the second metal pattern 21 may include at least one of nickel alloys such as nickel vanadium alloys, nickel tungsten alloys, and copper-nickel alloys.

Illustratively, formed by using the magnetron sputtering process may be used to form a film, and then the second metal pattern 21 may be patterned using a photolithographic process.

In order to achieve a better anti-oxidation effect, the weight percentage of nickel in the material of the second metal pattern 21 is greater than or equal to 50%.

Referring to FIG. 9, optical reflectivity-wavelength curves for nickel vanadium alloys under several annealing conditions are shown. The change of optical reflectivity before and after annealing can reflect the oxidation resistance performance of nickel vanadium alloy. As shown in FIG. 9, the reflectivity-wavelength curve after annealing at 150° C. for 30 minutes substantially coincides with the reflectivity-wavelength curve without annealing, and the reflectivity of the light-emitting baseplate after annealing at 250° C. for 30 minutes has no significant change compared with the reflectance of the non-annealed light-emitting baseplate, indicating that the nickel-vanadium alloy has good oxidation resistance performance and can provide oxidation resistance protection to the first metal pattern 11.

The results show that the oxidation resistance performance of nickel tungsten alloy is similar to that of nickel vanadium alloy, and the oxidation resistance performance of copper-nickel alloy is slightly worse. Therefore, the anti-oxidation effect of the second metal pattern 21 formed by using the nickel-vanadium alloy or the nickel-tungsten alloy is superior to the anti-oxidation effect of the second metal pattern 21 formed by using the copper-nickel alloy.

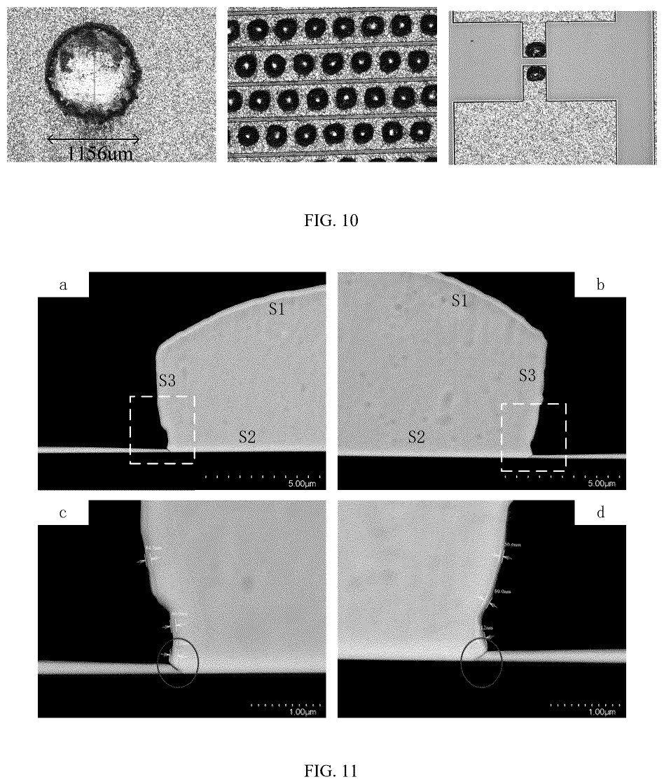

In addition, the nickel alloy has a good solder paste wettability, referring to FIG. 10, it shows that under the condition that the size of the steel mesh window is 1,000 μm, the spreading diameters of the solder paste after reflowing are all greater than 1,000 μm, and the spreading size of the solder paste is 1,156 μm as shown in the left part of FIG. 10, and it can be seen therefrom that the nickel alloy has a good solder paste wettability, facilitating the soldering of the light-emitting element.

In some embodiments, the material of the passivation layer 31 may include one or more of silicon nitride, silicon oxide, and silicon oxynitride.

In some embodiments, the material of the isolation layer 71 may include one or more of silicon nitride, silicon oxide, and silicon oxynitride.

The present disclosure also provides a light-emitting device including a light-emitting baseplate as provided in any one of the embodiments; and a light-emitting diode which is disposed at a side of the first metal pattern 11 away from the substrate 10 and connected to the first metal pattern 11, wherein the first metal pattern 11 is used for providing a driving signal to the light-emitting diode so as to drive the light-emitting diode to emit light.

As will be appreciated by those skilled in the art, the light-emitting device has the advantage of the above light-emitting baseplate.

The light-emitting diode may be a Micro Light Emitting Diode (Micro LED) and/or a Mini Light Emitting Diode (Mini LED), etc., and the present disclosure is not limited thereto. Wherein the Micro LED has a size of about 100 μm to about 300 μm. The Mini LED has a size of about 100 μm or less.

In some embodiments, the light-emitting device is a lighting device, which functions as a light source to provide a lighting function. For example, the light-emitting device may be a backlight module in a liquid crystal light-emitting device, a lamp for internal or external illumination, or various signal lamps, etc.

In other embodiments, the light-emitting device is a display device for achieving the function of displaying an image (i.e., a picture). The light-emitting device may include a display or a product including a display. Among them, the display may be a flat panel display (FPD), micro display, or the like. The display may be a transparent display or an opaque display if it is divided according to whether the user can see the scene behind the display. The display may be a flexible display or an ordinary display (which may be referred to as a rigid display) if it is divided according to whether the display can be bent or rolled. Illustratively, the product including the display may include a computer display, a television, a billboard, a laser printer with a display function, a telephone, a mobile phone, electronic paper, a personal digital assistant (PDA), a laptop computer, a digital camera, a tablet computer, a notebook computer, a navigator, a portable camcorder, a viewfinder, a vehicle, a large area wall, a screen of a theater or a stadium sign, etc.

The present disclosure also provides a preparation method for a light-emitting baseplate, including:

Step S01: providing a substrate 10.

Step S02: forming a first metal pattern 11 on a side of the substrate 10, wherein the first metal pattern 11 includes: a first surface S1 away from the substrate 10, a second surface S2 close to the substrate 10, and a first side surface S3 connecting the first surface S1 and the second surface S2, the first surface S1 includes a middle region, and an edge region located at the periphery of the middle region. Among them, the first surface S1 protrudes toward a side away from the substrate 10, and the protrusion height of the middle region is larger than that of the edge region.

The light-emitting baseplate provided in any one of the above embodiments can be obtained using the preparation method provided in the present disclosure.

In a specific implementation, various embodiments may be used to form the first metal pattern 11 on a side of the substrate 10, as exemplified below.

In some embodiments, the first metal pattern 11 may be formed by using a series of patterning processes such as film formation, exposure, development, and etching. For example, the first metal pattern 11 having a mushroom-shaped top surface can be finally obtained by etching by using a gray-scale mask in an exposure process, as shown in FIG. 1.

However, the thickness of the first metal pattern 11 formed by a single patterning process of the present embodiment is less, generally less than or equal to 2 μm, and therefore the first metal pattern 11 with a greater thickness requires multiple processes to be completed, the process flow is relatively complicated, and there is a risk of excessive stress.

In other embodiments, the first metal pattern 11 may also be formed by using an additive plating process. The process can naturally form a mushroom-like top surface due to the relatively fast rate of metal ion exchange in the middle region, resulting in a relatively fast growth rate in the middle region. In addition, by controlling parameters such as plating time, it is possible to form the first metal pattern 11 with a greater thickness, which simplifies the process flow, and reduces the risk of excessive stress.

Step S02 is described below by taking the host material of the first metal pattern 11 as copper as an example. In step S02, the step of forming the first metal pattern 11 on a side of the substrate 10 may specifically include:

Step S11: forming a seed layer on a side of the substrate 10.

Illustratively, a magnetron sputtering process may be used to sequentially form a buffer layer and a seed metal layer on a side of the substrate 10. The material of the buffer layer may include, for example, molybdenum, titanium, a nickel alloy, a molybdenum-neodymium alloy, or molybdenum, which can improve the adhesion of the film layer. The thickness of the buffer layer can be, for example, greater than or equal to 300 angstroms and less than or equal to 500 angstroms. Since the host material of the first metal pattern 11 is copper, copper may be selected as the material of the seed metal layer, and the thickness of the seed metal layer may be, for example, greater than or equal to 3,000 angstroms and less than or equal to 6,000 angstroms.

Step S12: patterning a pattern defining layer 130 on the side of the seed layer away from the substrate 10, and as shown in FIG. 13, the material of the pattern defining layer 130 is a removable insulating material, and the pattern defining layer 130 is provided with a plurality of openings 131 to expose the seed layer at corresponding positions.

Among them, the material of the pattern defining layer 130 can be an organic insulating material, for example, it can be a photosensitive resin, a photoresist, etc.; it may also be an inorganic material, for example, a material such as silicon oxide.

In particular implementations, the thickness of the pattern defining layer 130 may be determined based on the thickness of the first metal pattern 11, and the thickness of the pattern defining layer 130 may be controlled to be greater than the thickness of the first metal pattern 11 in order to prevent the material of the first metal pattern 11 from growing beyond the opening of the pattern defining layer 130. Illustratively, the thickness of the pattern defining layer 130 may be greater than or equal to 120% of the thickness of the first metal pattern 11 and less than or equal to 130% of the thickness of the first metal pattern 11, which may improve the plating uniformity of the first metal pattern 11.

In some embodiments, the included angle γ between the side surface of the pattern defining layer 130 facing the opening 131 and the bottom surface of the pattern defining layer 130 close to the substrate 10 is greater than or equal to 60° and less than or equal to 120°. The included angle γ may be, for example, 70°, 80°, 90°, 100°, 110° etc. In FIG. 13, the included angle γ is 80.45°.

By controlling the included angle γ to be greater than or equal to 60°, the included angle β between the first side surface S3 and the second surface S2 of the finally formed first metal pattern 11 can be made to be less than or equal to 120°, which is advantageous for improving the coverage of the subsequent film layers of the first metal pattern 11.

Illustratively, the material of the pattern defining layer 130 includes a resin substrate, a sensitizer filled in the resin substrate, a solvent, etc. The pattern defining layer 130 may be formed by using a series of patterning processes such as film formation, exposure, and development. In order to control the above-mentioned included angle γ to be greater than or equal to 60°, in some embodiments, the pattern defining layer 130 includes a resin material, and the relative molecular weight of the resin material is greater than or equal to 30,000 and less than or equal to 50,000. In this way, it is possible to increase the difference in developing properties between the exposed region and the non-exposed region in the exposure process for forming the pattern defining layer 130 in favor of increasing the included angle γ.

In order to control the above-mentioned included angle γ to be greater than or equal to 60°, in other embodiments, the pattern defining layer 130 includes a sensitizer, and the mass fraction of the sensitizer is greater than or equal to 20%. In this way, it is possible to increase the difference in developing properties between the exposed region and the non-exposed region in the exposure process for forming the pattern defining layer 130 in favor of increasing the included angle γ.

Step S13: forming a first metal material layer within the opening 131 of the pattern defining layer 130.

Illustratively, the first metal material layer may be formed by using an electroplating process, the current density of the electroplating may be 2ASD to 4ASD, and the thickness of the final first metal material layer may be 5 μm to 10 μm. Where ASD represents Amperes per square foot.

Illustratively, the first metal material layer metallic material may be formed by using a chemical plating or electrochemical process, and the present disclosure is not limited in this respect.

Step S14: removing the pattern defining layer 130. At this step, the pattern defining layer 130 may be peeled off.

Step S15: removing the part of the seed layer not covered by the first metal material layer by using an etching process to form a first metal pattern 11, wherein the first metal pattern 11 includes a seed layer 111 and a first metal material layer 112 remaining after the etching process is completed, as shown in any one of FIG. 2 to FIG. 8.

In the etching process of step S15, there is no need to protect the first metal material layer, so the surface of the first metal material layer is partially etched, and the seed layer 111 and the first metal material layer 112 obtained after the etching are completed form the first metal pattern 11.

In order to prevent oxidation of the first metal pattern 11, in the first embodiment, as shown in FIG. 2, after step S02, the above-mentioned preparation method may further include:

Step S21: forming a second metal pattern 21 on the side of the first metal pattern 11 away from the substrate 10, the second metal pattern 21 completely covering the first surface S1 and the first side surface S3.

FIG. 11 shows a cross-sectional view of the light-emitting baseplate after step S21 is completed; plan a and plan b in FIG. 11 respectively correspond to physical drawings at left and right positions of the light-emitting baseplate shown in FIG. 2; plan c is an enlarged view in a dashed box in plan a; and plan d is an enlarged view in a dashed box in plan b.

As shown in FIG. 11, the top surface S1 of the first metal pattern 11 forms a mushroom-shaped bulge, and the first side surface S3 is formed with a groove 12 (as shown in a dashed box in FIG. 11) at a bottom corner position close to the substrate 10, because, in the etching process of step S15, the bottom corner position is etched inwards, resulting in the bottom corner being retracted.

Illustratively, the deposition thickness of the second metal pattern 21 on the first surface S1 may be, for example, greater than or equal to 2000 angstroms and less than or equal to 6000 angstroms.

Illustratively, a layer of nickel alloy may be deposited on the surface of the first metal pattern 11 away from the substrate 10 by using a magnetron sputtering process, and then a series of patterning processes such as exposure, development, and etching processes may be used to form the second metal pattern 21, and the second metal pattern 21 comprehensively wraps the exposed first surface S1 and first side surface S3 of the first metal pattern 11, so that the material of the first metal material may be protected from oxidation in all directions.

In the present embodiment, as shown in FIG. 2, the design value of the first package length L1 may be set to 1 μm, and the finally formed first package length L1 is generally greater than or equal to 0.5 μm and less than or equal to 1.5 μm due to the presence of alignment errors between different layers in the manufacturing process.

In a second embodiment, after step S02, as shown in any one of FIG. 3 to FIG. 8, the above-mentioned preparation method may further include:

Step S31: forming a passivation layer 31 on a side of the first metal pattern 11 away from the substrate 10, the passivation layer 31 is provided with a first opening V1, and the first opening V1 is used for exposing the middle region of the first surface S1, and the passivation layer 31 covers at least the edge region of the first surface S1 and the first side surface S3.

Illustratively, a passivation material layer may first be integrally formed on the side of the first metal pattern 11 away from the substrate 10 by using a chemical vapor deposition process, that is, the orthographic projection of the passivation material layer on the substrate 10 covers the substrate 10 with the whole surface; and then using an exposure, development, and etching process to open a hole on the passivation material layer, namely, removing the passivation material layer covering the middle region of the first surface S1 to form a first opening V1, so as to obtain a passivation layer 31.

Step S32: forming a second metal pattern 21 is formed on the side of the passivation layer 31 away from the substrate 10, the second metal pattern 21 completely covers the middle region of the first surface S1, and the orthographic projection of the second metal pattern 21 on the substrate 10 at least partially covers the orthographic projection of the passivation layer 31 on the substrate 10.

Illustratively, the deposition thickness of the second metal pattern 21 on the first surface S1 may be, for example, greater than or equal to 2000 angstroms and less than or equal to 6000 angstroms.

Illustratively, a layer of nickel alloy may be deposited on the surface of the passivation layer 31 away from the substrate 10 by using a magnetron sputtering process, after which the second metal pattern 21 may be formed by using a series of patterning processes such as exposure, development, and etching processes.

As shown in FIG. 3, the boundary of the orthographic projection of the second metal pattern 21 on the substrate 10 is located between the boundary of the orthographic projection of the first opening V1 on the substrate 10 and the boundary of the orthographic projection of the first metal pattern 11 on the substrate 10.

For convenience of description, the distance between the boundary of the orthographic projection of the first opening V1 on the substrate 10 and the boundary of the orthographic projection of the second metal pattern 21 on the substrate 10 is defined as the second package length. As shown in FIG. 3, the design value for the second package length can be set to 2 μm, and the finally formed first package length L1 is typically greater than or equal to 1 μm and less than or equal to 3 μm due to alignment errors between the different layers in the manufacturing process.

As shown in FIG. 4, the boundary of the orthographic projection of the second metal pattern 21 on the substrate 10 is located on the side of the boundary of the orthographic projection of the first metal pattern 11 on the substrate 10 away from the orthographic projection of the first opening V1 on the substrate 10.

As previously described, the first package length L1 is the distance between the boundary of the orthographic projection of the first metal pattern 11 on the substrate 10 and the boundary of the orthographic projection of the second metal pattern 21 on the substrate 10. As shown in FIG. 4, the design value of the first package length L1 may be set to 1 μm, and the finally formed first package length L1 is typically greater than or equal to 0.5 μm and less than or equal to 1.5 μm due to the presence of alignment errors between the different layers in the manufacturing process.

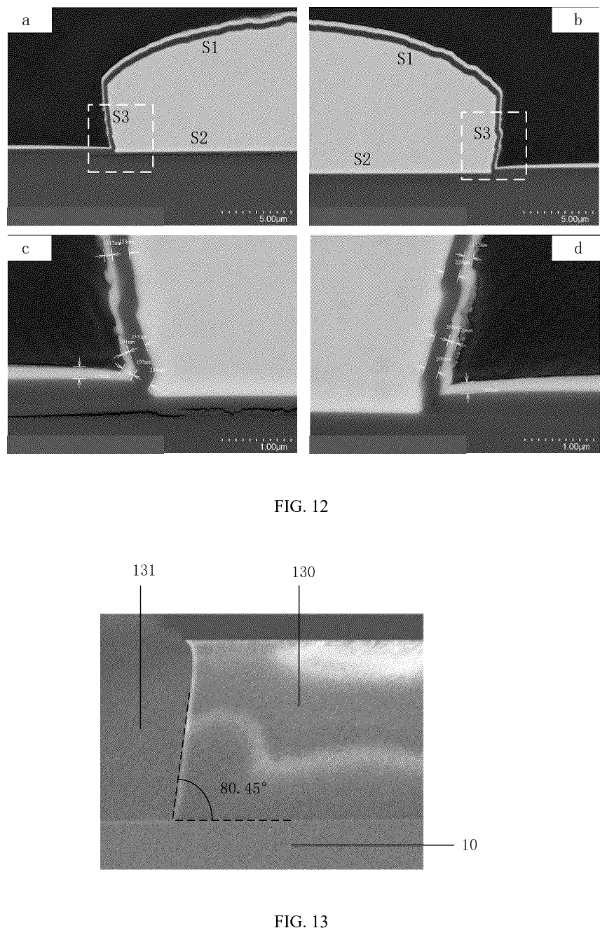

FIG. 12 shows a cross-sectional view of the light-emitting baseplate after step S32 is completed, and plan a and plan b in FIG. 12 respectively correspond to physical figures at the left and right positions of the light-emitting baseplate shown in FIG. 4, plan c is an enlarged view in a dashed box in plan a, and plan d is an enlarged view in a dashed box in plan b.

As shown in FIG. 12, the top surface S1 of the first metal pattern 11 forms a mushroom-shaped bulge, and the first side surface S3 is formed with a groove 12 (as shown in a dashed box in FIG. 12) at a bottom corner position close to the substrate 10, because, in the etching process of step S15, the bottom corner position is etched inwards, resulting in the bottom corner being retracted.

In some embodiments, after step S31, and before step S32, the method further includes: Step S41: forming a flat layer 51 on the side of the passivation layer 31 away from the substrate 10, the orthographic projection of the flat layer 51 on the substrate 10 completely overlaps with the orthographic projection of the passivation layer 31 on the substrate 10, and the surface of the side of the flat layer 51 away from the substrate 10 is a plane parallel to the substrate 10, so that the planarity of the light-emitting baseplate can be improved.

Accordingly, in step S32, the step of forming the second metal pattern 21 on the side of the passivation layer 31 away from the substrate 10 includes:

Step S42: forming the second metal pattern 21 on the side of the flat layer 51 away from the substrate 10.

Illustratively, a passivation material layer and a flat material layer may first be integrally formed on the side of the first metal pattern 11 away from the substrate 10, namely, orthographic projections of the passivation material layer and the flat material layer on the substrate 10 cover the substrate 10 with the whole surface; then, the first opening V1 on the passivation layer 31 and the flat layer 51 are simultaneously formed by processes such as exposure and development.

In some embodiments, after step S41 and before step S42, the method further includes:

Step S51: forming an isolation layer 71 on the side of the flat layer 51 away from the substrate 10, a second opening V2 is provided on the isolation layer 71, an orthographic projection of the second opening V2 on the substrate 10 at least partially overlaps with an orthographic projection of the first opening V1 on the substrate 10, and the isolation layer 71 covers the surface of the flat layer 51 facing the second metal pattern 21 and the side surface of the flat layer 51 facing the first opening V1.

As shown in FIG. 7 or FIG. 8, by providing an isolation layer 71 between the above-described flat layer 51 and the second metal pattern 21, the adhesion of the second metal pattern 21 can be improved, the intrusion of external water and oxygen can be prevented, and water absorption or oxidation of the material of the flat layer 51 can be prevented.

It should be noted that the preparation method may also include more steps, which may be determined according to actual needs, and the present disclosure is not limited thereto. Reference may be made to the above description of the light-emitting baseplate for a detailed description of the preparation method and technical effects, which will not be repeated here.

In the present disclosure, “plurality of” means two or more, and “at least one” means one or more, unless otherwise specified.

In the present disclosure, the terms “up”, “down”, etc. indicate orientation or positional relationships based on the orientation or positional relationships shown in the accompanying drawings, only for the convenience of describing and simplifying the description of the present disclosure, and not to indicate or imply that the device or component referred to must have a specific orientation, be constructed and operated in a specific orientation, and therefore cannot be understood as a limitation of the present disclosure.

In this specification, the terms “including”, “comprising”, or any other variation thereof are intended to encompass non-exclusive inclusion, such that a process, method, product, or equipment that includes a series of elements not only includes those elements, but also includes other elements not explicitly listed, or also includes elements inherent to such process, method, product, or equipment. Without further limitations, the elements limited by the statement “including one . . . ” do not exclude the existence of other identical elements in the process, method, commodity, or device that includes the said elements.

The terms “one embodiment”, “some embodiments”, “exemplary embodiments”, “one or more embodiments”, “examples”, “one example”, “some examples”, etc. referred to in this specification are intended to indicate that specific features, structures, materials, or characteristics related to the embodiment or example are included in at least one embodiment or example of the present disclosure. The schematic representation of the above terms may not necessarily refer to the same embodiment or example. Furthermore, the specific features, structures, materials, or features described may be included in any one or more embodiments or examples in any appropriate manner.

In this specification, relational terms such as first and second are only used to distinguish one entity or operation from another entity or operation, without necessarily requiring or implying any such actual relationship or order between these entities or operations.

When describing some embodiments, the expressions “coupled” and “connected” may be used. For example, when describing some embodiments, the term “connection” may be used to indicate direct physical or electrical contact between two or more components. For example, when describing some embodiments, the term “coupled” may be used to indicate direct physical or electrical contact between two or more components. However, the terms “coupled” or “communicatively coupled” may also refer to two or more components that do not have direct contact with each other but still cooperate or interact with each other. The embodiments of the present disclosure are not necessarily limited to the content of this specification.

“At least one of A, B, and C” has the same meaning as “at least one of A, B, or C” and includes the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

As used in this specification, the term “if” is optionally interpreted as meaning “when” or “at” or “in response to determination” or “in response to detection” depending on the context. Similarly, depending on the context, the phrases “if it is determined . . . ” or “if it is detected [stated condition or event]” are optionally interpreted as referring to “when it is determined . . . ” or “in response to being determined . . . ” or “when it is detected [stated condition or event]” or “in response to being detected [stated condition or event]”.

The use of “used for” or “configured to” in this specification implies an open and inclusive language, which does not exclude devices that are applicable or configured to perform additional tasks or steps.

The use of “based on” or “according to” in this specification implies openness and inclusiveness. A process, step, calculation, or other action based on one or more of the conditions or values may be based on other conditions or exceed the values in practice. In practice, a process, step, calculation, or other action based on one or more of the conditions or values may be based on other conditions or exceed the values.

As used in this specification, “about”, “roughly”, or “approximately” includes the value described and the average value within an acceptable deviation range of a specific value, where the acceptable deviation range is determined by persons skilled in the art taking into account the measurement being discussed and the errors associated with a specific amount of measurement (i.e., limitations of the measurement system).

As used in this specification, “parallel”, “vertical”, “equal”, and “flush” include the described situation and situations that are similar to the described situation. The range of such similar situations is within the acceptable deviation range, where the acceptable deviation range is determined by ordinary technical personnel in the field considering the measurement being discussed and the errors related to a specific amount of measurement (i.e., the limitations of the measurement system). For example, “parallel” includes absolute parallel and approximate parallel, where the acceptable deviation range for approximate parallel can be within 5°. “Vertical” includes absolute vertical and approximate vertical, where the acceptable deviation range for approximate vertical can also be within 5°. “Equality” includes absolute equality and approximate equality, where the acceptable deviation range of approximate equality, for example, can be equal. The difference between the two is less than or equal to 5% of either. “Flush” includes absolute flush and approximate flush, where the acceptable deviation range for approximate flush, for example, can be that the distance between the two is less than or equal to 5% of the size of either.

It should be understood that when a layer or component is referred to as being on another layer or substrate, it can be that the layer or component is directly on another layer or substrate, or there can be an intermediate layer between the layer or component and another layer or substrate.

This specification describes exemplary embodiments with reference to sectional and/or floor plans as idealized exemplary drawings. In the attached figure, for clarity, the thickness of the layers and regions has been enlarged. Therefore, it can be assumed that changes in shape relative to the drawings may occur due to factors such as manufacturing technology and/or tolerances. Therefore, exemplary embodiments should not be interpreted as limited to the shape of the area shown herein, but rather include shape deviations caused by, for example, manufacturing. For example, the etched area shown as a rectangle will typically have curved features. Therefore, the areas shown in the drawings are essentially illustrative, and their shapes are not intended to show the actual shape of the device's area, nor are they intended to limit the scope of exemplary embodiments.

Finally, it should be noted that the above embodiments are only used to illustrate the technical solution of the present disclosure, and not to limit it. Although detailed explanations of the present disclosure have been provided with reference to the aforementioned embodiments, those skilled in the art should understand that they can still modify the technical solutions recorded in the aforementioned embodiments, or equivalently replace some of the technical features therein; and these modifications or replacements do not make the essence of the corresponding technical solutions deviate from the spirit and scope of the technical solutions of the embodiments of the present disclosure.

1. A light-emitting baseplate, comprising:
a substrate; and
a first metal pattern, disposed on a side of the substrate, and comprising: a first surface away from the substrate, a second surface close to the substrate, and a first side surface connecting the first surface and the second surface, wherein the first surface comprises a middle region, and an edge region at a periphery of the middle region;
wherein the first surface protrudes toward a side away from the substrate, and a protrusion height of the middle region is greater than a protrusion height of the edge region.

2. The light-emitting baseplate according to claim 1, wherein the first surface further comprises:
a sub-middle region, located between the middle region and the edge region, wherein a protrusion height of the sub-middle region is less than the protrusion height of the middle region and greater than the protrusion height of the edge region.

3. The light-emitting baseplate according to claim 1, wherein a protrusion height of the first surface gradually decreases from a center of the first surface to an edge of the first surface; and
a ratio of a difference between the protrusion heights of the middle region and the edge region to the protrusion height of the edge region is greater than or equal to 0.1, and less than or equal to 0.4.

4. The light-emitting baseplate according to claim 1, wherein an orthographic projection of the first surface on the substrate covers an orthographic projection of the second surface on the substrate, and an area of the orthographic projection of the first surface on the substrate is larger than an area of the orthographic projection of the second surface on the substrate.

5. The light-emitting baseplate according to claim 1, wherein an included angle between the first side surface and the second surface is greater than or equal to 80°, and less than or equal to 120°.

6. The light-emitting baseplate according to claim 1, wherein the first metal pattern further comprises:
a first cross section, parallel to the substrate and intersecting an edge of the first surface, wherein an included angle between the first cross section and the first side surface is an acute angle.

7. The light-emitting baseplate according to claim 1, wherein the first side surface is provided with a groove recessed toward inside of the first metal pattern, the groove is located at a position of the first side surface close to the substrate.

8. The light-emitting baseplate according to claim 1, wherein the light-emitting baseplate further comprises:
a second metal pattern, disposed on a side of the first metal pattern away from the substrate, wherein the second metal pattern completely covers the first surface and the first side surface.

9. The light-emitting baseplate according to claim 8, wherein the second metal pattern is provided with a fine seam close to a position where the first side surface intersects the second surface.

10. The light-emitting baseplate according to claim 1, wherein the light-emitting baseplate further comprises:
a passivation layer, disposed on a side of the first metal pattern away from the substrate, wherein a first opening is provided on the passivation layer, the first opening is used for exposing the middle region of the first surface, and the passivation layer covers at least the edge region of the first surface and the first side surface; and
a second metal pattern, disposed on a side of the passivation layer away from the substrate, wherein the second metal pattern completely covers the middle region of the first surface, an orthographic projection of the second metal pattern on the substrate at least partially covers an orthographic projection of the passivation layer on the substrate.

11. The light-emitting baseplate according to claim 10, wherein a boundary of the orthographic projection of the second metal pattern on the substrate is located between a boundary of an orthographic projection of the first opening on the substrate and a boundary of an orthographic projection of the first metal pattern on the substrate.

12. The light-emitting baseplate according to claim 10, wherein a boundary of the orthographic projection of the second metal pattern on the substrate is located on a side of a boundary of an orthographic projection of the first metal pattern on the substrate away from the orthographic projection of the first opening on the substrate.

13. The light-emitting baseplate according to claim 10, wherein the light-emitting baseplate further comprises:
a flat layer, located between the passivation layer and the second metal pattern, wherein an orthographic projection of the flat layer on the substrate completely overlaps the orthographic projection of the passivation layer on the substrate, a surface of a side of the flat layer away from the substrate is a plane parallel to the substrate.

14. The light-emitting baseplate according to claim 13, wherein the light-emitting baseplate further comprises:
an isolation layer, disposed between the flat layer and the second metal pattern, wherein a second opening is provided on the isolation layer, an orthographic projection of the second opening on the substrate at least partially overlaps an orthographic projection of the first opening on the substrate, the isolation layer covers a surface of the flat layer facing the second metal pattern and a side surface of the flat layer facing the first opening.

15. The light-emitting baseplate according to claim 13, wherein the flat layer comprises a first flat pattern overlapping the first metal pattern in a normal direction of the substrate, a thickness of the first flat pattern is greater than 0, and less than or equal to 1 μm.

16-17. (canceled)

18. The light-emitting baseplate according to claim 8, wherein a boundary of an orthographic projection of the first metal pattern on the substrate is located within a boundary of an orthographic projection of the second metal pattern on the substrate, and a distance between the boundary of the orthographic projection of the first metal pattern on the substrate and the boundary of the orthographic projection of the second metal pattern on the substrate is greater than or equal to 0.5 μm, and less than or equal to 1.5 μm.

19-20. (canceled)

21. The light-emitting baseplate according to claim 1, wherein an included angle formed by the intersection of the first surface and the first side surface is a rounded angle.

22. (canceled)

23. A light-emitting device, comprising:
the light-emitting baseplate according to claim 1; and
a light-emitting diode, disposed on a side of the first metal pattern away from the substrate, and connected to the first metal pattern, wherein the first metal pattern is used for providing a driving signal to the light-emitting diode, to drive the light-emitting diode to emit light.

24. A preparation method of a light-emitting baseplate, comprising:
providing a substrate;
forming a first metal pattern on a side of the substrate, wherein the first metal pattern comprises: a first surface away from the substrate, a second surface close to the substrate, and a first side surface connecting the first surface and the second surface, the first surface comprises a middle region, and an edge region at a periphery of the middle region; wherein the first surface protrudes toward a side away from the substrate, and a protrusion height of the middle region is greater than a protrusion height of the edge region.

25. The preparation method according to claim 24, wherein the step of forming a first metal pattern on a side of the substrate comprises:
forming a seed layer on a side of the substrate;
patterning to form a pattern defining layer on a side of the seed layer away from the substrate, wherein a material of the pattern defining layer is a removable insulating material, the pattern defining layer is provided with a plurality of openings to expose the seed layer at corresponding positions;
forming a first metal material layer within openings of the pattern defining layer;
removing the pattern defining layer;
removing a portion of the seed layer not covered by the first metal material layer using an etching process to form the first metal pattern, wherein the first metal pattern comprises a seed layer and a first metal material layer remaining after the etching process is completed.

26-27. (canceled)
